(19) United States
(12) Patent Application Publication
(10) Pub. No.: US 2017/0062486 A1
(43) Pub. Date: Mar. 2, 2017

(54) ARRAY SUBSTRATE AND MANUFACTURING METHOD THEREOF, DISPLAY DEVICE

(71) Applicants: Boe Technology Group Co., Ltd., Beijing (CN); Hefei Xinsheng Optoelectronics Technology Co., Ltd., Hefei, Anhui (CN)

(72) Inventors: Min ZHANG, Beijing (CN); Binbin CAO, Beijing (CN)

(21) Appl. No.: 14/914,076

(22) PCT Filed: Aug. 10, 2015
(86) PCT No.: PCT/CN2015/086460

§ 371 Date: Feb. 24, 2016

(30) Foreign Application Priority Data
Apr. 7, 2015 (CN) 201510161244.2

(51) Int. Cl. H01L 27/12; H01L 21/311

(52) U.S. Cl. CPC H01L 27/1248; H01L 27/1262; H01L 27/124; H01L 21/31138

(57) ABSTRACT

The present disclosure provides an array substrate and manufacturing method thereof, and a display device. Moreover, it relates to the technical field of display apparatus and can solve the problem that the organic insulating layer in an existing array substrate easily causes deficiencies in other structures. The array substrate of the present disclosure comprises an insulating layer. The insulating layer is provided with an opening and comprises: a first insulating layer; a second insulating layer arranged on the first insulating layer. A slope angle of the second insulating layer at the opening is smaller than a slope angle of the first insulating layer.

### RELATED APPLICATIONS

The present application is the U.S. national phase entry of PCT/CN2015/086460, with an international filing date of Aug. 10, 2015, which claims the benefit of Chinese Patent Application No. 201510161244.2, filed on Apr. 7, 2015, the entire disclosures of which are incorporated herein by reference.

### FIELD

The present disclosure relates to the technical field of display apparatus, specifically to an array substrate and manufacturing method thereof, and a display device.

### BACKGROUND

An array substrate of a display device is provided with many insulating layers for separating different structures. An organic insulating layer made from organic insulating material (e.g., polyethylene, polytetrafluoroethylene, etc.) is increasingly used due to its advantages such as simple process and low cost.

However, the organic insulating layer is always thick and also has a large slope angle at its opening, thus photoresist on the organic insulating layer easily flows and aggregates at the opening edge. The aggregated photoresist is difficult to remove thoroughly, thus it would result in photoresist residue and further cause that the opening edge cannot form a correct structure, thereby influencing display.

For example, as shown in FIGS. 1, 2, the edge part of an array substrate of a liquid crystal display device is provided with a connecting area for connecting leads (gate line lead, data line lead 2, common electrode line lead, etc.) to a driving chip. When an organic insulating layer 1 is used as a passivation layer between the data line leads 2 and pixel electrodes, the organic insulating layer 1 needs to be provided with an opening 19 in the connecting area to expose connectors 21 (PAD) at ends of the data line leads 2. In order to connect the chip to the connectors 21, the opening 19 of the organic insulating layer 1 in the connecting area must be relatively large, and each opening 19 corresponds to ends of a plurality of data line leads 2. After the opening 19 is formed, a transparent conductive layer 3 (such as indium tin oxide layer) is further deposited to form a pixel electrode or common electrode. Obviously, the transparent conductive layer 3 in the opening 19 should be removed completely. However, as stated above, a photoresist 9 remains at the opening edge, and the transparent conductive layer 3 under the residual photoresist 9 cannot be removed, as a result the data line leads 2 are mutually conducting, resulting in deficiencies (DDS deficiency) such as bright line.

### SUMMARY

With regard to the problem that the organic insulating layer in the existing array substrate easily causes deficiencies in other structures, the present disclosure provides an array substrate that can avoid deficiencies in other structures and a manufacturing method thereof, and a display device.

According to a first aspect of the present disclosure, an array substrate is provided which may comprise an insulating layer. The insulating layer is provided with an opening and comprises:

a first insulating layer; and

a second insulating layer arranged on the first insulating layer, a slope angle of said second insulating layer at the opening is smaller than a slope angle of said first insulating layer.

According to an embodiment, said insulating layer may be an organic insulating layer; said first insulating layer may be a first organic insulating layer; said second insulating layer may be a second organic insulating layer.

According to another embodiment, the first organic insulating layer at said opening may have a slope angle of 50 to 60 degrees; the second organic insulating layer at said opening may have a slope angle of 40 to 50 degrees; the difference between the slope angle of the first organic insulating layer and the slope angle of the second organic insulating layer at said opening may be 5 to 15 degrees.

According to a further embodiment, said first organic insulating layer may have a thickness of 1 to 2 microns; said second organic insulating layer may have a thickness of 1 to 2 microns; said organic insulating layer may have a thickness of 2 to 3 microns.

According to yet another embodiment, the material of said organic insulating layer may comprise a photosensitizer and a film-forming material, and the content of photosensitizer in said first organic insulating layer may be different from the content of photosensitizer in said second organic insulating layer.

According to an embodiment, the photosensitizer in said organic insulating layer may be a negative photosensitizer; the content of is photosensitizer in said first organic insulating layer may be greater than the content of photosensitizer in said second organic insulating layer.

According to another embodiment, the photosensitizer in said organic insulating layer may be a positive photosensitizer; the content of photosensitizer in said first organic insulating layer may be less than the content of photosensitizer in said second organic insulating layer.

According to another embodiment, in said first organic insulating layer and second organic insulating layer, the mass percent of photosensitizer in the layer with higher content of photosensitizer may be 3% to 5%; the mass percent of photosensitizer in the layer with lower content of photosensitizer may be 1% to 3%; the difference between the mass percents of photosensitizer in the two layers may be 1.5% to 2.5%.

According to a further embodiment, said array substrate may comprise a connecting area for connecting a driving chip and leads located within said connecting area, at least partial opening of said organic insulating layer is arranged in the connecting area; said organic insulating layer is located above said leads, each opening of said organic insulating layer in the connecting area is provided with ends of a plurality of leads; said organic insulating layer is at least provided with a conductive structure.

According to yet another embodiment, said leads are data line leads; said organic insulating layer is a passivation layer arranged above the data line leads; said conductive structure is a pixel electrode or common electrode.

According to a second aspect of the present disclosure, a method of manufacturing the above array substrate is provided, which may comprise:

forming the first insulating layer and the second insulating layer, and forming an opening in the first insulating layer and the second insulating layer.

According to an embodiment, said forming the first insulating layer and the second insulating layer, and forming an opening in the first insulating layer and the second insulating layer comprise: forming a first insulating layer; forming a second insulating layer; simultaneously forming is an opening penetrating said first insulating layer and said second insulating layer.

According to a third aspect of the present disclosure, a display device is provided, which comprises the above array substrate.

In the array substrate of the present disclosure, the insulating layer (in particular organic insulating layer) is divided into at least two layers (which may also be more layers), and the upper layer has a smaller slope angle such that the slope of the opening edge becomes gentle to exhibit a stepped shape. This can reduce aggregation of the photoresist at the opening edge (i.e., reducing the photoresist residue), thereby ensuring that other structures located above the insulating layer can be formed correctly, decreasing the probability of occurrence of deficiencies such as DDS, and improving the product quality.

### BRIEF DESCRIPTION OF DRAWINGS

FIG. 1 is a local structural schematic diagram of an existing array substrate in a connecting area;

FIG. 2 is a local sectional structural schematic diagram of an existing array substrate in a connecting area;

FIG. 3 a local structural schematic diagram of an array substrate according to an embodiment of the present disclosure in a connecting area; and

FIG. 4 is a local sectional structural schematic diagram of an array substrate according to an embodiment of the present disclosure in a connecting area.

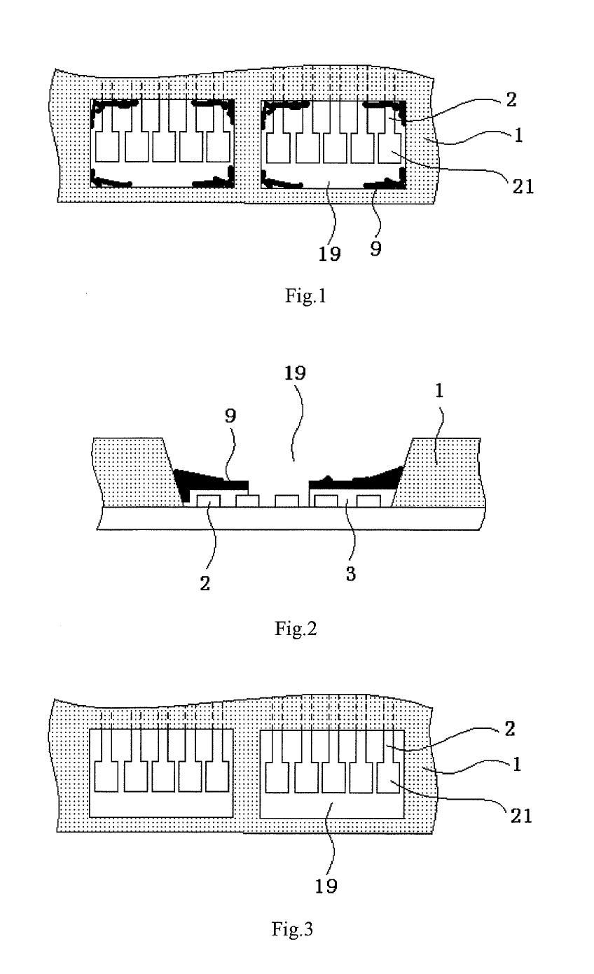

The reference signs are: 1 organic insulating layer; 11 first organic insulating layer; 12 second organic insulating layer; 19 opening; 2 data line lead; 21 connector; 3 conductive layer; 9 photoresist.

### DETAILED DESCRIPTION OF THE INVENTION

To enable those skilled in the art to better understand the technical solution of the present disclosure, the present disclosure is further is described in detail as follows in combination with the figures and specific implementations.

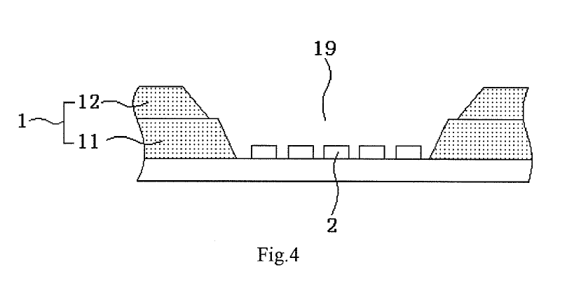

As shown in FIG. 3 and FIG. 4, the present embodiment provides an array substrate comprising an insulating layer provided with an opening 19.

The array substrate of the present embodiment may be an array substrate for use in a liquid crystal display device, an organic light-emitting diode display device, and so on. The array substrate comprises a plurality of insulating layers for separating the structures in different layers. At least one of these insulating layers is provided with an opening 19 (called via hole) to electrically connect the structures above and below it.

The above insulating layer comprises a first insulating layer with a second insulating layer arranged on the first insulating layer. The slope angle of the second insulating layer at the opening 19 is smaller than the slope angle of the first insulating layer.

In one example, the above insulating layer is an organic insulating layer 1, and correspondingly, the first insulating layer is a first organic insulating layer 11 and the second insulating layer is a second organic insulating layer 12. Therefore, the second organic insulating layer 12 is arranged on the first organic insulating layer 11, and the slope angle of the second organic insulating layer 12 at the opening 19 is smaller than the slope angle of the first organic insulating layer 11.

In other words, in the array substrate of the present embodiment, at least partial insulating layer may be the organic insulating layer 1 made from organic insulating material. The organic insulating layer 1 is divided into at least two layers, and the upper layer has a smaller slope angle such that the slope of the edge of the opening 19 becomes gentle to exhibit a stepped shape. This can reduce aggregation of the photoresist at the edge of the opening 19 (i.e., reducing the photoresist residue), thereby ensuring that other structures located above the organic insulating layer 1 can be formed correctly, decreasing the probability of occurrence of deficiencies is such as DDS, and improving the product quality.

Certainly, the above organic insulating layer 1 is not limited to consisting of two layers, which may also be divided into three or more layers. When the organic insulating layer 1 consists of three or more layers, the upper the layer is, the smaller the slope angle can be. Certainly, when the organic insulating layer 1 comprises three or more layers, two adjacent layers may have the same slope angle or the slope angles thereof may also have other relationships. However, it should at least be ensured that there is the first organic insulating layer 11 and the second organic insulating layer 12 thereon which satisfy the above relationship. Since the essential situation of dividing the organic insulating layer 1 into more layers is similar to that of dividing it into two layers, detailed description thereof is not given here.

In an illustrative embodiment, the slope angle of the first organic insulating layer 11 at the opening 19 is 50 to 60 degrees; the slope angle of the second organic insulating layer 12 at the opening 19 is 40 to 50 degrees; the difference between the slope angle of the first organic insulating layer 11 and the slope angle of the second organic insulating layer 12 at the opening 19 is 5 to 15 degrees.

As stated above, the slope angle of the first organic insulating layer 11 should be larger than the slope angle of the second organic insulating layer 12. Moreover, when the slope angles of the two layers fall within the above ranges, they can achieve a good effect of preventing aggregation of the photoresist.

In an illustrative embodiment, the first organic insulating layer 11 has a thickness of 1 to 2 microns; the second organic insulating layer 12 has a thickness of 1 to 2 microns; the organic insulating layer 1 has a thickness of 2 to 3 microns.

Generally speaking, the total thickness of the organic insulating layer 1 is 2 to 3 microns. In this case, the thickness of two layers therein may fall within the above range, whereas the allocation of specific thicknesses of two layers therein can be adjusted by those skilled in the art based on is needs.

In an illustrative embodiment, the material of the organic insulating layer 1 comprises a photosensitizer and a film-forming material, and the contents of photosensitizer in the first organic insulating layer 11 and the second organic insulating layer 12 are different.

That is to say, the organic insulating layer 1 may consist of a photosensitive material similar to “photoresist”. Such organic insulating layer 1 comprises a film-forming material used for forming the film material body and a photosensitive photosensitizer. The photosensitizer may react to illumination and change the solubility of the film-forming material, such that the organic insulating layer 1 can be formed into a desired pattern as long as it is exposed and developed, without etched.

When the organic insulating layer 1 contains the photosensitizer, the slope angle of the organic insulating layer 1 can be correspondingly changed as long as the content of photosensitizer is changed.

Specifically, as regards the organic insulating layer 1 which uses a negative photosensitizer, the content of photosensitizer in the first organic insulating layer 11 is greater than the content of photosensitizer in the second organic insulating layer 12.

The negative photosensitizer is also a photosensitizer used in a negative photoresist, which refers to a photosensitizer capable of making the organic insulating layer 1 become insoluble upon illumination by light. When such photosensitizer is used, as shown in Table 1 as follows, the higher the content of photosensitizer is, the larger the resulting slope angle will be. Therefore, the content of photosensitizer in the first organic insulating layer 11 needs to be relatively higher.

TABLE 1
Impact of Negative Photosensitizer on Slope Angle

| | No. | | |
|---|---|---|---|
| | A | B | C |
| Nominal | 3~5 wt % (about | 2~3 wt % (about | <2.5 wt % (about |
| photosensitizer | 4 wt %) | 2.5 wt %) | 1.5 wt %) |
| content of | | | |
| product | | | |
| Stable | >40 mj | >50 mj | >60 mj |
| exposure | | | |
| Film thickness | 2.5 μm | 2.5 μm | 2.5 μm |
| Mask slot | 13 μm | 13 μm | 13 μm |
| width | | | |
| bottom width | 5.18 μm | 5.3 μm | 5.36 μm |
| of opening | | | |
| Slope angle | 58° | 51.8° | 49.9° |

In the above table, the film-forming material used in the organic insulating layer 1 is primarily an acrylic resin, and the photosensitizer material is primarily propylene glycol monomethyl ether acetate. The manufacturers of the three kinds of organic insulating layer material products are: A organic insulating layer material: DOW; B organic is insulating layer material: Dongjin; C organic insulating layer material: JSR, respectively. Certainly, the organic insulating layer 1 further contains other known ingredients such as pigment, detailed description of which is not given here. Meanwhile, the bottom width, the slope angle, etc. of the opening 19 of the respective organic insulating layers 1 are obtained by observing the section at the opening 19 of the organic insulating layer 1 using a scanning electron microscope.

As an alternative of the present embodiment, the photosensitizer in the organic insulating layer 1 is a positive photosensitizer. Then, the content of photosensitizer in the first organic insulating layer 11 is less than the content of photosensitizer in the second organic insulating layer 12.

That is to say, the positive photosensitizer may also be used, i.e., using a photosensitizer that makes the organic insulating layer 1 become soluble after it is illuminated by light. When the positive photosensitizer is used, the higher the content of photosensitizer is, the smaller the resulting slope angle will be. Therefore, the content of photosensitizer in the first organic insulating layer 11 needs to be relatively lower.

Certainly, the photosensitizers and the film-forming materials in the is first organic insulating layer 11 and the second organic insulating layer 12 may the same or different, and the properties of the photosensitizers may be different. For example, when the photosensitizer in the first organic insulating layer 11 is a positive photosensitizer, the photosensitizer in the second organic insulating layer 12 is a negative photosensitizer, or vice versa, as long as the slope angle of the second organic insulating layer 12 at the opening 19 is smaller than the slope angle of the first organic insulating layer 11.

In an illustrative embodiment, in the first organic insulating layer 11 and the second organic insulating layer 12, the mass percent of photosensitizer in the layer with higher content of photosensitizer is 3% to 5%, the mass percent of photosensitizer in the layer with lower content of photosensitizer is 1% to 3%, and the difference between the mass percents of photosensitizer in the two layers is 1.5% to 2.5%.

That is to say, when the photosensitizer is used to adjust the slope angle of the organic insulating layer 1, the contents of photosensitizer in the two layers can be set to satisfy the above condition so as to reach the aforesaid slope angle range. Specifically, when the negative photosensitizer is used, the content of photosensitizer in the first insulating layer can be set to be 3% to 5% and the content of photosensitizer in the second insulating layer can be set to be 1% to 3%. When the positive photosensitizer is used, the content of photosensitizer in the first insulating layer is set to be 1% to 3% and the content of photosensitizer in the second insulating layer is set to be 3% to 5%.

In an illustrative embodiment, the array substrate of the present embodiment comprises a connecting area for connecting a driving chip and leads located in the connecting area. At least partial opening 19 of the organic insulating layer 1 is arranged in the connecting area; the organic insulating layer 1 is located above the leads, each opening 19 of the organic insulating layer 1 in the connecting area is provided with ends of a plurality of leads, and the organic insulating layer 1 is at least provided with a conductive structure.

That is to say, the edge part of the array substrate may be provided with a connecting area for connecting leads to a driving chip, and the organic insulating layer 1 is provided with an opening 19 in the connecting area to make ends (such as “connector 21”) of the leads as covered thereby exposed and connected to the driving chip. Moreover, each opening 19 of the organic insulating layer 1 in the connecting area should correspond to ends of a plurality of leads. Meanwhile, the array substrate further comprises at least one other conductive structure (such as pixel electrode, common electrode, etc.) located above the organic insulating layer 1. As stated above, in the prior art, the opening 19 of the organic insulating layer 1 in the above connecting area easily leads to formation of photoresist residue at the edge, whereas such photoresist residue would cause the subsequently formed pattern of the conductive structure to be incorrect, such that the plurality of leads are mutually conducting. However, the overall slope angle at the opening 19 of the organic insulating layer 1 of the array substrate of the present embodiment is relatively smaller, thus it can avoid the photoresist residue and thereby prevent the respective leads from being mutually conducting.

In an illustrative embodiment, the leads are data line leads 2, the organic insulating layer 1 is a passivation layer arranged above the data line leads 2, and the conductive structure is a pixel electrode or common electrode.

That is to say, as shown in FIG. 3, FIG. 4, the organic insulating layer 1 may be a passivation layer covering the data line leads 2, and at that time a pixel electrode or common electrode is further to be formed on the organic insulating layer 1 (depending on the specific form of the array substrate). The reason is that the aforesaid problem that the photoresist residue causes the leads to be conducting mostly occurs in the data line leads 2 in practice.

Certainly, the practical array substrate should further comprise other structures such as a gate insulating layer and an interlayer insulating layer (located between the pixel electrode and the common electrode). These structures may also be distributed in the connecting area. However, they is are not described here in detail and not shown in the figures either because they are known to those skilled in the art and not directly relevant to the present disclosure.

Certainly, the application of the present embodiment is not limited to that. For example, the organic insulating layer 1 may also be a gate insulating layer covering the gate, and at that time the leads are gate line leads. The conductive structure on the organic insulating layer 1 may be the data line lead 2, pixel electrode, common electrode, etc. Or, the opening 19 of the organic insulating layer 1 may also be not only located in the connecting area, but also distributed in the display area for display (e.g., opening for connecting the source and drain to the active area). Certainly, the opening in the display area would generally not cause different leads to be connected, but may lead to other deficiencies in structures, which is thus also applicable to the technical solution in the present disclosure.

Certainly, the insulating layer in the present embodiment may also be an inorganic insulating layer made from inorganic material, and at that time it may also be divided into two layers with different slope angles. The present embodiment only takes the organic insulating layer 1 as an example for explanation just because the organic insulating layer 1 always has a large thickness and easily causes the aforesaid problem of photoresist residue.

A further embodiment of the present disclosure provides a method of manufacturing the above array substrate, comprising:

forming a first insulating layer and a second insulating layer, and forming an opening in the first insulating layer and the second insulating layer.

In an illustrative embodiment, the above steps of forming a first insulating layer and a second insulating layer, and forming an opening in the first insulating layer and the second insulating layer specifically comprise:

forming a first insulating layer;

forming a second insulating layer;

simultaneously forming an opening penetrating the first insulating layer and the second insulating layer.

That is to say, after the first insulating layer and the second insulating layer are formed, it is possible to form an opening simultaneously in the two layers to thereby simplify the process. Certainly, it is also feasible to first form the first insulating layer and form an opening therein, and then form the second insulating layer and further form an opening therein.

The above insulating layers may be organic insulating layers. Correspondingly, the first insulating layer is a first organic insulating layer and the second insulating layer is a second organic insulating layer.

Specifically, there are various ways to form an opening in the first organic insulating layer and the second organic insulating layer. For example, as regards the above organic insulating layer containing a photosensitizer, it can be directly exposed and developed. Since specific processes of forming an opening is known to those skilled in the art, detailed description thereof is not given here.

However, if the above insulating layer is not an organic insulating layer, the step of forming an opening therein may further comprise other steps of coating a photoresist, etching, lifting off the photoresist, etc., detailed description of which is not given here.

An embodiment of the present disclosure further provides a display device comprising the above array substrate.

Specifically, the display device provided by the present embodiment may be any product or component having display function such as liquid crystal display panel, electronic paper, OLED panel, mobile phone, tablet computer, television, display, notebook computer, digital frame, navigator, and so on.

It can be understood that the above embodiments are illustrative embodiments used only for explaining the principle of the present disclosure, but the present disclosure is not limited to that. Those ordinarily skilled in the art can make various variations and improvements without departing from the spirit and essence of the present disclosure. These variations and improvements are also regarded as the protection scope of the present disclosure.

1-13. (canceled)

14. An array substrate comprising an insulating layer provided with an opening, wherein, said insulating layer comprises:
a first insulating layer;
a second insulating layer arranged on the first insulating layer, wherein a slope angle of said second insulating layer at the opening being smaller than a slope angle of said first insulating layer.

15. The array substrate according to claim 14, wherein
said insulating layer is an organic insulating layer;
wherein said first insulating layer is a first organic insulating layer; and
wherein said second insulating layer is a second organic insulating layer.

16. The array substrate according to claim 15, wherein
the first organic insulating layer at said opening has a slope angle of 50 to 60 degrees;
wherein the second organic insulating layer at said opening has a slope angle of 40 to 50 degrees; and
wherein the difference between the slope angle of the first organic insulating layer and the slope angle of the second organic insulating layer at said opening is 5 to 15 degrees.

17. The array substrate according to claim 15, wherein
said first organic insulating layer has a thickness of 1 to 2 microns;
wherein said second organic insulating layer has a thickness of 1 to 2 microns; and
wherein said organic insulating layer has a thickness of 2 to 3 microns.

18. The array substrate according to claim 15,
wherein the material of said organic insulating layer comprises a photosensitizer and a film-forming material, and the content of photosensitizer in said first organic insulating layer is different from the content of photosensitizer in said second organic insulating layer.

19. The array substrate according to claim 18, wherein
the photosensitizer in said organic insulating layer is a negative photosensitizer; and
wherein the content of photosensitizer in said first organic insulating layer is greater than the content of photosensitizer in said second organic insulating layer.

20. The array substrate according to claim 18, wherein
the photosensitizer in said organic insulating layer is a positive photosensitizer; and
wherein the content of photosensitizer in said first organic insulating layer is less than the content of photosensitizer in said second organic insulating layer.

21. The array substrate according to claim 18, wherein, in said first organic insulating layer and second organic insulating layer,
the mass percent of photosensitizer in the layer with higher content of photosensitizer is 3% to 5%;
the mass percent of photosensitizer in the layer with lower content of photosensitizer is 1% to 3%; and
the difference between the mass percents of photosensitizer in the two layers is 1.5% to 2.5%.

22. The array substrate according to claim 15, wherein
said array substrate comprises a connecting area for connecting a driving chip and leads located within said connecting area, wherein at least partial opening of said organic insulating layer is arranged in the connecting area; wherein said organic insulating layer is located above said leads, each opening of said organic insulating layer in the connecting area is provided with ends of a plurality of leads; and
wherein said organic insulating layer is at least provided with a conductive structure.

23. The array substrate according to claim 16, wherein
said array substrate comprises a connecting area for connecting a driving chip and leads located within said connecting area, wherein at least partial opening of said organic insulating layer is arranged in the connecting area; wherein said organic insulating layer is located above said leads, each opening of said organic insulating layer in the connecting area is provided with ends of a plurality of leads; and
wherein said organic insulating layer is at least provided with a conductive structure.

24. The array substrate according to claim 17, wherein
said array substrate comprises a connecting area for connecting a driving chip and leads located within said connecting area, wherein at least partial opening of said organic insulating layer is arranged in the connecting area; wherein said organic insulating layer is located above said leads, each opening of said organic insulating layer in the connecting area is provided with ends of a plurality of leads; and
wherein said organic insulating layer is at least provided with a conductive structure.

25. The array substrate according to claim 18, wherein
said array substrate comprises a connecting area for connecting a driving chip and leads located within said connecting area, wherein at least partial opening of said organic insulating layer is arranged in the connecting area; wherein said organic insulating layer is located above said leads, each opening of said organic insulating layer in the connecting area is provided with ends of a plurality of leads; and
wherein said organic insulating layer is at least provided with a conductive structure.

26. The array substrate according to claim 19, wherein
said array substrate comprises a connecting area for connecting a driving chip and leads located within said connecting area, wherein at least partial opening of said organic insulating layer is arranged in the connecting area; wherein said organic insulating layer is located above said leads, each opening of said organic insulating layer in the connecting area is provided with ends of a plurality of leads; and
wherein said organic insulating layer is at least provided with a conductive structure.

27. The array substrate according to claim 20, wherein
said array substrate comprises a connecting area for connecting a driving chip and leads located within said connecting area, wherein at least partial opening of said organic insulating layer is arranged in the connecting area; wherein said organic insulating layer is located above said leads, each opening of said organic insulating layer in the connecting area is provided with ends of a plurality of leads; and
wherein said organic insulating layer is at least provided with a conductive structure.

28. The array substrate according to claim 21, wherein
said array substrate comprises a connecting area for connecting a driving chip and leads located within said connecting area, wherein at least partial opening of said organic insulating layer is arranged in the connecting area; wherein said organic insulating layer is located above said leads, each opening of said organic insulating layer in the connecting area is provided with ends of a plurality of leads; and
wherein said organic insulating layer is at least provided with a conductive structure.

29. The array substrate according to claim 22, wherein
said leads are data line leads;
wherein said organic insulating layer is a passivation layer arranged above the data line leads; and
wherein said conductive structure is a pixel electrode or common electrode.

30. A method of manufacturing an array substrate, wherein said array substrate comprises an insulating layer provided with an opening, said insulating layer comprises:
a first insulating layer;
a second insulating layer arranged on the first insulating layer, a slope angle of said second insulating layer at the opening being smaller than a slope angle of said first insulating layer,
said method of manufacturing an array substrate comprising:
forming said first insulating layer and said second insulating layer, and forming an opening in said first insulating layer and said second insulating layer.

31. The method of manufacturing an array substrate according to claim 30, wherein, said forming said first insulating layer and said second insulating layer, and forming an opening in said first insulating layer and said second insulating layer comprise:
forming a first insulating layer;
forming a second insulating layer;
simultaneously forming an opening penetrating said first insulating layer and said second insulating layer.

32. A display device, comprising:
an array substrate comprising an insulating layer provided with an opening, wherein, said insulating layer comprises:
a first insulating layer;
a second insulating layer arranged on the first insulating layer, a slope angle of said second insulating layer at the opening being smaller than a slope angle of said first insulating layer.

33. The display device according to claim 32, wherein
said insulating layer is an organic insulating layer;
said first insulating layer is a first organic insulating layer; and
said second insulating layer is a second organic insulating layer.
